(19) United States
(12) Patent Application Publication
(10) Pub. No.: US 2022/0130644 A1
(43) Pub. Date: Apr. 28, 2022

(54) PLASMA PROCESSING APPARATUS, PLASMA PROCESSING METHOD, AND CONDUCTIVE MEMBER

(71) Applicants: Noa Leading Co., Ltd., Yokohama-shi (JP); TOSHIBA MATERIALS CO., LTD., Yokohama-shi (JP)

(72) Inventors: Masahiro YOKOTA, Fukaya (JP); Akihiko HAPPOYA, Yokohama (JP); Ken TAKAHASHI, Itabashi (JP); Shusuke MORITA, Yokohama (JP); Jiro OSHIMA, Fuchu (JP); Shuichi SAITO, Yokohama (JP); Noriaki YAGI, Yokohama (JP); Atsuya SASAKI, Yokohama (JP)

(73) Assignees: Noa Leading Co., Ltd., Yokohama-shi (JP); TOSHIBA MATERIALS CO., LTD., Yokohama-shi (JP)

(21) Appl. No.: 17/438,184

(22) PCT Filed: Mar. 13, 2020
(86) PCT No.: PCT/JP2020/011050

§ 371 Date: Sep. 10, 2021

(30) Foreign Application Priority Data
Mar. 15, 2019 (JP) 2019-048408

(51) Int. Cl. H01J 37/32

(52) U.S. Cl. CPC H01J 37/32458; H01J 2237/334; H01J 37/3211

(57) ABSTRACT

A plasma processing apparatus includes: a chamber including a first member, and a second member detachable from the first member; a conductive member disposed between the first member and the second member; and a first high frequency power supply generating plasma in the chamber. The conductive member includes a resin member made of a resin material, and a metal film covering a surface of the resin member.

### TECHNICAL FIELD

Embodiments relate to a plasma processing apparatus, a plasma processing method, and a conductive member.

### BACKGROUND ART

In a semiconductor device such as memory, a logic circuit, a power device, a TFT (Thin Film Transistor: thin film transistor) substrate of a liquid crystal panel, or the like, elements such as transistors, capacitors, diodes, and the like are integrated, and these elements are connected to each other by conductive portions such as interconnects, vias, etc. To integratedly form such elements and conductive portions in the manufacturing of the semiconductor device, the formation of thin films such as conductive films, insulating films, semiconductor films, and the like on a substrate made of silicon, silicon carbide, sapphire, gallium nitride, glass, etc., and the patterning of these thin films are repeated.

In the manufacturing processes of the semiconductor device, other than the formation and patterning of the thin films, various processing such as ion implantation for controlling the electrical properties of the semiconductors, annealing for controlling the properties of the thin films and/or the interfaces of the thin films, cleaning of the entire substrate and/or the surface of the pattern, rinsing for surface modification, planarization such as CMP (Chemical Mechanical Polishing: chemical mechanical polishing), etc., are appropriately combined. Then, patterning is performed, and although the number of times is different according to the type and/or generation of the semiconductor device, the patterning is normally performed about several tens of times; finally, the semiconductor device is completed.

However, fluctuation unavoidably occurs in the various processing described above. For example, when patterning a thin film, and when shape error such as fluctuation of the dimension, an abnormality of the shape, etc., occurs in the pattern of the thin film, the position shifts between the patterns above and below when stacking the patterns; and unintended voids and/or protrusions are formed. Also, the shape error causes fluctuation of the electrical characteristics; and the performance as a semiconductor device can no longer be ensured. Also, the controllability of the various processing greatly affects the yield of the semiconductor device. For example, the occurrence of dust and/or contamination that exceeds the allowable amount causes defects of the pattern and/or degradation of the electrical characteristics of the thin film, and reduces the yield of the semiconductor device.

On the other hand, semiconductor devices are being downscaled year by year.

FIG. 24 is a graph showing the trend of semiconductor device downscaling, in which the horizontal axis is the decade, and the vertical axis is transistor integration.

As shown in FIG. 24, at least up to the present, the integration of semiconductor devices is exponentially increasing according to Moore's law. Accordingly, the patterns of semiconductor devices are being downscaled. In recent years, devices in which the channel length of the transistor is not more than 10 nm also have been announced. Therefore, it is necessary to downscale the mask patterns used in the patterning as well; for example, it is necessary to set the line width to be not more than 10 nm.

The shape error relatively increases when the mask pattern is downscaled; therefore, a shape error that previously was not a problem can no longer be tolerated hereafter. For example, a slight shape error markedly reduces the yield of the semiconductor device. Therefore, the controllability that is necessary for the patterning becomes more stringent. Also, as the pattern is downscaled, low-level dust and/or contamination that previously was not a problem becomes a problem hereafter. Therefore, higher controllability will be necessary for various processing of the manufacturing processes of semiconductor devices in the future. In particular, the improvement of the controllability of the patterning is a crucial requirement for downscaling the semiconductor device.

Many factors that determine the controllability of the patterning exist; among these, however, examples of factors in plasma etching are illustrated as follows. In plasma etching, the portion that is not covered with the mask pattern is physicochemically etched using ions and/or radicals excited by plasma.

FIGS. 25A to 25E are cross-sectional views showing general plasma etching processes.

FIG. 26 is a drawing showing typical factors to be controlled in plasma etching.

A foundation member 300 is prepared as shown in FIG. 25A. The foundation member 300 may be a cleaned substrate, or may be a thin film that is formed on a substrate. Then, as shown in FIG. 25B, a thin film 301 is deposited on the entire surface on the foundation member 300. The method for depositing the thin film 301 is, for example, sputtering, CVD (Chemical Vapor Deposition: chemical vapor deposition), etc. Then, as shown in FIG. 25C, a photoresist is coated onto the thin film 301, and exposing and developing are performed to form a resist pattern 302 in which a prescribed pattern is formed. Then, as shown in FIG. 25D, the thin film 301 is patterned by etching using plasma by using the resist pattern 302 as a mask. Then, as shown in FIG. 25E, for example, the resist pattern 302 is removed by ashing. Thus, the thin film 301 is patterned into a prescribed shape.

As shown in FIG. 26, among the factors that determine the controllability of the plasma etching, dimensional factors related to the pattern formation such as the dimension of the resist pattern 302, the shape of the thin film 301, the etching selectivity between the resist pattern 302 and the thin film 301, the etching selectivity between the thin film 301 and the foundation member 300, the etching residue of the thin film 301, etc., are large. Also, contamination due to impurities caused by the plasma etching apparatus, the etching gas, and the like, structural changes of the foundation member due to ion implantation, etc., also greatly affect the electrical characteristics of the semiconductor device. Also, residue of etching products, structural changes of the mask pattern, etc., are factors that affect the controllability of the subsequent processes.

When an error occurs in the dimension of the resist pattern 302, and for example, in the case that the plasma etching process shown in FIG. 26 is a process of forming the gate of a transistor, fluctuation of the channel length of the transistor occurs. Therefore, the electrical characteristics of the transistor are directly affected.

For example, when an error occurs in the shape of the thin film 301 after the etching, and when the plasma etching process shown in FIG. 26 is a process of forming an interconnect, and the interconnect is buried in an insulating film in a subsequent process, there are cases where voids (voids) are undesirably formed in the insulating film; signals may be delayed due to the change of the capacitance between the interconnects; and the reliability may be reduced. Also, when an etching product remains at the connection portion between the interconnect and the transistor, the electrical resistance becomes large, which causes wiring delay and/or wiring breakage defects.

When the etching selectivity between the thin film 301 and the foundation member 300 decreases, so-called over-etching occurs when etching the thin film 301; and the foundation member 300 also is undesirably etched. Therefore, the shape precision decreases. Also, when the over-etching is pronounced, the recess that is formed by the over-etching extends through the foundation member 300 and undesirably reaches a member (not illustrated) that is located below the foundation member 300. When the underlying member and the thin film 301 are conductive portions and the foundation member 300 is an insulating film, the conductive portions that would originally be insulated contact each other, short-circuit and/or leakage occurs, and the semiconductor device no longer operates correctly.

FIG. 27 is a graph showing the margin of the etching amount that is tolerated, in which the horizontal axis is the etching time, and the vertical axis is the defect rate.

In the patterning of the thin film described in reference to FIGS. 25A to 25E and FIG. 26, it is common for the etching amount to be controlled by the etching time. As shown in FIG. 27, when the etching amount is insufficient, etching residue occurs and causes defective components; and when the etching amount is excessive, the foundation member is undesirably etched excessively, and as expected, defective components are caused. An etching amount such that etching residue does not occur and the etching amount of the foundation member is not more than the allowable amount is the margin of the etching amount that is tolerated; however, the margin becomes narrow as the semiconductor device is downscaled.

Thus, various shape errors occur even when performing etching 1 time. As described above, when manufacturing the semiconductor device, it is necessary to perform etching about several tens of times; therefore, the shape errors that occur each time etching is performed undesirably accumulate. Therefore, even when the shape error that is generated by performing etching 1 time is micro, the characteristics and/or the yield of the final semiconductor device are greatly affected. Also, the shape error relatively increases as semiconductor devices are downscaled now and in the future; therefore, the allowable margin becomes remarkably small, and the difficulty of the etching process increases even more.

Also, as semiconductor devices are downscaled, the controllability of the etching also is affected by micro changes of dimensions due to the deposition of products on the interior wall of the chamber and the wear of parts due to plasma, the matching state of the output of the high frequency power, etc.; and the equipment difference between processing apparatuses and the change over time of the same apparatus also are problematic.

Therefore, a mechanism is practically employed in which parameters such as the flow rate, pressure, and temperature of the gas, the output and matching state of the high frequency power, etc., are constantly monitored at the apparatus side; and a warning is displayed or the processing is interrupted in the case of an abnormality. However, it is difficult to directly monitor the state of the interior wall of the chamber, slight wear of the parts, etc.; and a check of etching characteristics by a so-called apparatus QC (Quality Check) and/or a check by a final quality evaluation of a test pattern formed in a substrate are performed. Also, for an etching apparatus, etc., maintenance of the apparatus is regularly performed to suppress change over time due to wear of the members and/or the change of the interior wall state, and the replacement of the consumable members and the cleaning of the interior of the apparatus are performed.

However, even when maintenance is regularly performed, the etching characteristics of the apparatus after maintenance are not always perfectly uniform. For example, a slight mounting error between parts affects the etching characteristics. This causes not only errors each time maintenance of the same apparatus is performed, but also errors between the apparatuses; and when multiple chambers are provided in one apparatus to improve the productivity, errors occur also between the chambers.

Therefore, the error described above is reduced by matching by performing apparatus QC. However, to this end, workers and work time are necessary; the time that the expensive processing apparatus cannot be used in production lengthens; therefore, the productivity of the semiconductor device is markedly reduced.

### PRIOR ART DOCUMENTS

### Patent Literature

[Patent Literature 1] Japanese Patent Application 2003-303882 (Kokai)

### SUMMARY OF INVENTION

### Technical Problem

The invention was conceived in consideration of the problems described above, and is directed to provide a plasma processing apparatus, a plasma processing method, and a conductive member that have stable operations.

### Solution to Problem

A plasma processing apparatus according to an embodiment, includes: a chamber including a first member, and a second member detachable from the first member; a conductive member disposed between the first member and the second member; and a first high frequency power supply generating plasma in the chamber. The conductive member includes a resin member made of a resin material, and a metal film covering a surface of the resin member.

A plasma processing method according to an embodiment, includes: placing a work in a chamber including a first member and a second member, disposing a conductive member between the first member and the second member, and compressing the conductive member, the conductive member including a metal film on a surface of a resin member, the resin member being made of a resin material; and generating plasma in the chamber by applying a high frequency current.

### BRIEF DESCRIPTION OF DRAWINGS

FIG. 1 is a graph showing an example of relationship between etching amount, maintenance, and part replacement of a conventional plasma etching apparatus, in which the horizontal axis is time, and the vertical axis is the etching amount.

FIG. 2 is a graph showing an example of relationship between electrical resistance value and replacement timing of a conductive member, in which the horizontal axis is time, and the vertical axis is electrical resistance value between a lower part and an upper part of a chamber.

FIG. 3 is a graph showing relationship between supply power and etching amount, in which the horizontal axis is electrical power supplied to a holder, and the vertical axis is the etching amount.

FIG. 4 is a cross-sectional view showing a plasma etching apparatus according to a first embodiment.

FIG. 5A is a plan view showing a lower part of the plasma etching apparatus according to the first embodiment; and

FIG. 5B is a cross-sectional view along line A-A′ shown in FIG. 5A.

FIG. 6A is a perspective view showing a conductive member of the plasma etching apparatus according to the embodiment; and FIG. 6B is a cross-sectional view of FIG. 6A.

FIG. 7A is a graph showing an example of relationship between the etching amount, the maintenance, and the part replacement of the plasma etching apparatus according to the first embodiment, in which the horizontal axis is time, and the vertical axis is the etching amount; FIG. 7B is a graph showing an example of relationship between the impedance, the maintenance, and the part replacement of the plasma etching apparatus according to the first embodiment, in which the horizontal axis is time, and the vertical axis is the impedance; and FIG. 7C is a graph showing an example of relationship between the impedance, the maintenance, and the part replacement of a plasma etching apparatus according to a comparative example, in which the horizontal axis is time, and the vertical axis is the impedance.

FIG. 8A is a cross-sectional view showing a shape of the conductive member when the chamber is opened; FIG. 8B is a cross-sectional view showing a shape of the conductive member when the chamber is sealed; and FIG. 8C is a photograph showing the conductive member in a state in which a crack has occurred in a metal film.

FIG. 9A is a graph showing the change of the resistance value when repeatedly applying a compressive force to the conductive member in which the metal film is made of nickel and has a thickness of 100 nm while changing the compression ratio, in which the horizontal axis is the compression ratio, and the vertical axis is the electrical resistance value; and FIG. 9B is a graph of the data shown in FIG. 9A that shows the effects of the compression ratio on the electrical resistance value, in which the horizontal axis is the compression ratio when compressed, and the vertical axis is the electrical resistance value when compressed and when released.

FIG. 10A is a graph showing the change of the resistance value when repeatedly applying a compressive force to the conductive member in which the metal film is made of nickel and has a thickness of 400 nm while changing the compression ratio, in which the horizontal axis is the compression ratio, and the vertical axis is the electrical resistance value; and FIG. 10B is a graph of the data shown in FIG. 10A that shows the effects of the compression ratio on the electrical resistance value, in which the horizontal axis is the compression ratio when compressed, and the vertical axis is the electrical resistance value when compressed and when released.

FIG. 11A is a graph showing the change of the resistance value when repeatedly applying a compressive force to the conductive member in which the metal film is made of nickel and has a thickness of 800 nm while changing the compression ratio, in which the horizontal axis is the compression ratio, and the vertical axis is the electrical resistance value; and FIG. 11B is a graph of the data shown in FIG. 11A that shows the effects of the compression ratio on the electrical resistance value, in which the horizontal axis is the compression ratio when compressed, and the vertical axis is the electrical resistance value when compressed and when released.

FIG. 12A is a graph showing the change of the resistance value when repeatedly applying a compressive force to the conductive member in which the metal film is made of copper and has a thickness of 100 nm while changing the compression ratio, in which the horizontal axis is the compression ratio, and the vertical axis is the electrical resistance value; and FIG. 12B is a graph of the data shown in FIG. 12A that shows the effects of the compression ratio on the electrical resistance value, in which the horizontal axis is the compression ratio when compressed, and the vertical axis is the electrical resistance value when compressed and when released.

FIG. 13A is a graph showing the change of the resistance value when repeatedly applying a compressive force to the conductive member in which the metal film is made of copper and has a thickness of 400 nm while changing the compression ratio, in which the horizontal axis is the compression ratio, and the vertical axis is the electrical resistance value; and FIG. 13B is a graph of the data shown in FIG. 13A that shows the effects of the compression ratio on the electrical resistance value, in which the horizontal axis is the compression ratio when compressed, and the vertical axis is the electrical resistance value when compressed and when released.

FIG. 14A is a graph showing the change of the resistance value when repeatedly applying a compressive force to the conductive member in which the metal film is made of copper and has a thickness of 800 nm while changing the compression ratio, in which the horizontal axis is the compression ratio, and the vertical axis is the electrical resistance value; and FIG. 14B is a graph of the data shown in FIG. 14A that shows the effects of the compression ratio on the electrical resistance value, in which the horizontal axis is the compression ratio when compressed, and the vertical axis is the electrical resistance value when compressed and when released.

FIG. 15 is a graph showing the effect of the composition and film thickness of the metal film on the relationship between the compression ratio and the electrical resistance value, in which the horizontal axis is the compression ratio when compressed, and the vertical axis is the electrical resistance value when released.

FIG. 16 is a graph showing the favorable range of use of the conductive member, in which the horizontal axis is the film thickness of the metal film, and the vertical axis is the compression ratio directly before the resistance value undergoes an irreversible change.

FIG. 17 is a plan view showing a lower part of a plasma etching apparatus according to a second embodiment.

FIG. 18A is a cross-sectional view showing a conductive member of the plasma etching apparatus according to the second embodiment; FIG. 18B is a perspective view showing the conductive member in the released state; and FIG. 18C is a perspective view showing the conductive member in the compressed state.

FIG. 19A is a plan view showing a test member used as the etching object of a test example; FIG. 19B is a cross-sectional view showing the test member before the etching; and FIG. 19C is a cross-sectional view showing the test member after the etching.

FIGS. 20A and 20B are graphs showing etching rate distribution for a carbon film, in which the horizontal axis is the position, and the vertical axis is the etching rate.

FIGS. 21A and 21B are graphs showing etching rate distribution for a silicon oxide film, in which the horizontal axis is the position, and the vertical axis is the etching rate.

FIGS. 22A and 22B are graphs showing etching rate distribution for a silicon nitride film, in which the horizontal axis is the position, and the vertical axis is the etching rate.

FIG. 23 is a graph showing existence or absence of nickel contamination, in which the horizontal axis is sample, and the vertical axis is nickel detection amount of a test member after the etching.

FIG. 24 is a graph showing a trend of semiconductor device downscaling, in which the horizontal axis is a decade, and the vertical axis is transistor integration.

FIGS. 25A to 25E are cross-sectional views showing general plasma etching processes.

FIG. 26 is a drawing showing typical factors to be controlled in plasma etching.

FIG. 27 is a graph showing a margin of an etching amount that is tolerated, in which the horizontal axis is an etching time, and the vertical axis is a defect rate.

FIG. 28 is a drawing showing an example of factors that affect the controllability of the etching.

FIG. 29 is a drawing showing an example of a general inductively coupled plasma dry etching apparatus.

FIG. 30 is a perspective view showing a conductive member.

FIG. 31 is a graph showing bias voltage dependence of etching rate, in which the horizontal axis is the bias voltage, and the vertical axis is the etching rate.

### DESCRIPTION OF EMBODIMENTS

### Cause Investigation of Problem

The inventors considered the causes of the fluctuation of the plasma etching described above.

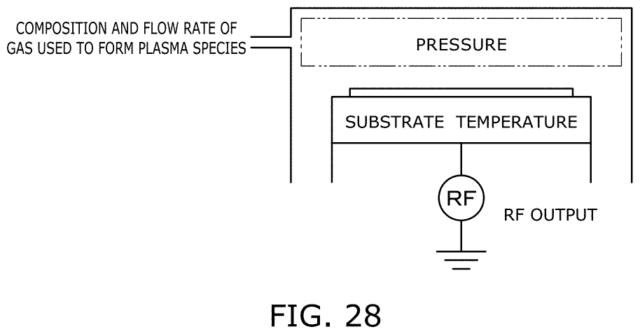

FIG. 28 is a drawing showing an example of factors that affect the controllability of the etching.

As shown in FIG. 28, at least the following factors are considered to be factors that affect the controllability of the etching.

(1) Fluctuation of the composition, flow rate, and pressure of the gas used to form the plasma species

(2) Fluctuation of the output of the high frequency power supply for forming the plasma

(3) Fluctuation of the processing temperature

(4) Fluctuation of the output of the high frequency power supply for applying the bias

(5) Drift of the calibration curve of the bias voltage and the etching rate

(6) Damage of the parts in the chamber due to the etching and the repair of the damage

(7) Degradation and replacement of the parts included in the plasma processing apparatus

For the fluctuation of the composition, flow rate, and pressure of the gas used to form the plasma species of (1) described above, normally, a high-purity gas that is procured is introduced to the chamber directly from a supply line by performing flow rate control. Therefore, unless there is leakage of the supply pipe and/or the chamber, etc., it is considered unlikely that fluctuation of the composition of the plasma species would cause fluctuation of the etching rate. Also, the flow rate and pressure of the gas can be easily controlled and measured; therefore, it is also considered unlikely that the flow rate and pressure of the gas would greatly fluctuate.

For the fluctuation of the output of the high frequency power supply for forming the plasma of (2) described above, for some plasma processing apparatus, the amount of processing is not constantly excessive, and may be normal, excessively small, and then excessive. Therefore, unless there is a failure of the high frequency power supply, it is considered unlikely that the fluctuation of the output of the high frequency power supply would cause fluctuation of the etching rate. Also, because similar fluctuation occurs in many plasma processing apparatuses, failure of the high frequency power supply is also considered unlikely.

For the fluctuation of the processing temperature of (3) described above, the temperature of the wafer in the plasma processing may fluctuate for various factors. However, the temperature of the wafer can be directly measured; and a significant relationship between the etching amount and the measured temperature of the wafer has not been confirmed. Therefore, the effect of the fluctuation of the processing temperature on the etching rate is considered to be limited if any.

The fluctuation of the output of the high frequency power supply for applying the bias of (4) described above also is considered unlikely to cause fluctuation of the etching rate due to the same reasons as those of (2) described above.

For the drift of the calibration curve of the bias voltage and the etching rate of (5) described above, for some plasma processing apparatus, the amount of processing is not constantly excessive as described above; and there are also cases where the amount of processing is normal or excessively small. Therefore, it is considered unlikely that drift of the calibration curve would cause fluctuation of the etching rate; and even if the accuracy of the calibration curve is further increased, it is considered that the effect on causing the fluctuation of the etching rate to converge would be low.

For the damage of the parts in the chamber due to the etching and the repair of the damage of (6) described above, maintenance is regularly performed for each apparatus as described above; and the damaged portions are repaired. Therefore, if there is a correlation between the fluctuation and the timing of the maintenance, it is estimated that the damage due to the etching and the repair of the damage are causes of fluctuation.

For the degradation and replacement of the parts of (7) described above as well, the consumable parts are regularly replaced in each apparatus as described above. Therefore, if there is a correlation between the fluctuation and the timing of the replacement, it is estimated that the degradation and replacement of the parts are causes of fluctuation.

A typical plasma processing apparatus that was the object of investigations by the inventors will now be described.

An inductively coupled plasma (ICP: Inductively Coupled Plasma)-type dry etching apparatus will be described as an example of the plasma processing apparatus.

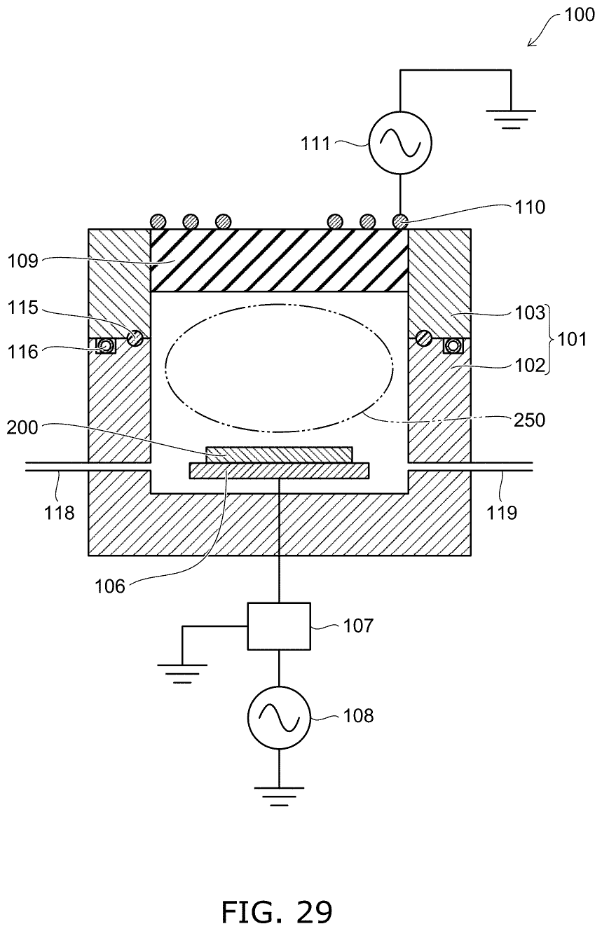

FIG. 29 is a drawing showing an example of a general inductively coupled plasma dry etching apparatus.

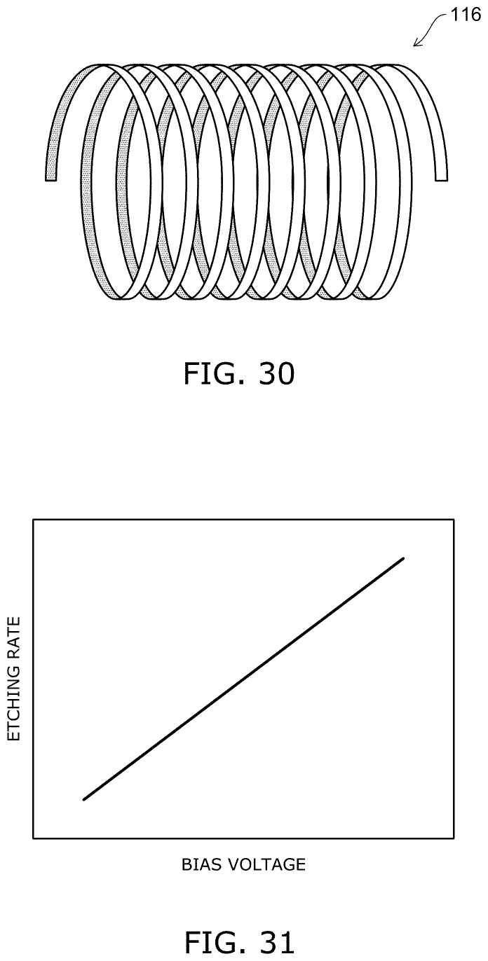

FIG. 30 is a perspective view showing a conductive member.

As shown in FIG. 29, a chamber 101 is provided in a plasma etching apparatus 100. The chamber 101 includes a lower part 102 and an upper part 103. Normally, the lower part 102 is fixed to a frame or the like and is grounded. The upper part 103 is provided to be openable and closable with respect to the lower part 102, and functions as the lid of the chamber 101.

A holder 106 is provided in the lower part 102. The holder 106 holds a wafer 200 as a work. The holder 106 is connected to a high frequency power supply 108 via a voltage controller 107. The voltage controller 107 and the high frequency power supply 108 each are grounded. A dielectric plate 109 is provided in the upper part 103; a coil 110 is provided on the dielectric plate 109; and the coil 110 is connected to a high frequency power supply 111. The high frequency power supply 111 also is grounded.

An airtight member 115 for guaranteeing the airtightness in the chamber 101 and a conductive member 116 for guaranteeing the conduction between the lower part 102 and the upper part 103 are provided at the boundary portion between the lower part 102 and the upper part 103. The airtight member 115 is, for example, an O-ring; and the conductive member 116 is, for example, a metal coil. Also, the lower part 102 and the upper part 103 are coupled by bolts and nuts made of metal. Thereby, the lower part 102 and the upper part 103 are mechanically coupled and have the same potential. A supply pipe 118 that supplies a gas into the chamber 101 and an exhaust pipe 119 that exhausts the gas from the interior of the chamber 101 are provided in the chamber 101.

As shown in FIG. 30, the conductive member 116 is a coil-shaped member that is formed by winding a metal band into a spiral shape. For example, a groove that is slightly shallower than the diameter of the conductive member 116 is formed in the surface of the lower part 102 of the chamber 101 that abuts the upper part 103; and the conductive member 116 is housed in the groove. Thereby, when the upper part 103 is closed, the conductive member 116 is compressed and elastically deforms, and both the lower part 102 and the upper part 103 are pressed. As a result, the conduction via the conductive member 116 between the lower part 102 and the upper part 103 is ensured.

A plasma processing method that uses the plasma etching apparatus 100 will now be described.

As shown in FIG. 29, the wafer 200 is mounted to the holder 106. Also, the upper part 103 is coupled to the lower part 102; and the interior of the chamber 101 is set to an airtight state. Then, the interior of the chamber 101 is exhausted via the exhaust pipe 119; and a gas that is used to form the plasma species is introduced via the supply pipe 118. The high frequency power supply 111 supplies a high frequency current to the coil 110 in this state. The gas is ionized thereby, and plasma 250 is formed. Also, the high frequency power supply 108 supplies a high frequency current to the holder 106. Thereby, a bias voltage is applied to the plasma 250; and ions inside the plasma are accelerated and collide with the wafer 200. As a result, the wafer 200 is etched.

FIG. 31 is a graph showing the bias voltage dependence of the etching rate, in which the horizontal axis is the bias voltage, and the vertical axis is the etching rate.

As the bias voltage increases as shown in FIG. 31, the acceleration voltage of the ions increases, and the etching rate increases. The correlation is different according to the material of the work; the correlation also is different according to the design of the apparatus; there are also individual differences between apparatuses. Therefore, the relationship between the bias voltage and the etching rate is pre-calibrated. Then, when etching is performed, the bias voltage that corresponds to the target etching rate is input to the voltage controller 107. Thereby, the voltage controller 107 controls the output of the high frequency power supply 108; and the desired etching rate is realized. The wafer 200 is etched a constant amount by performing etching at a constant etching rate for a constant amount of time.

The inventors confirmed the following trends by investigating many plasma processing apparatuses over a long period of time.

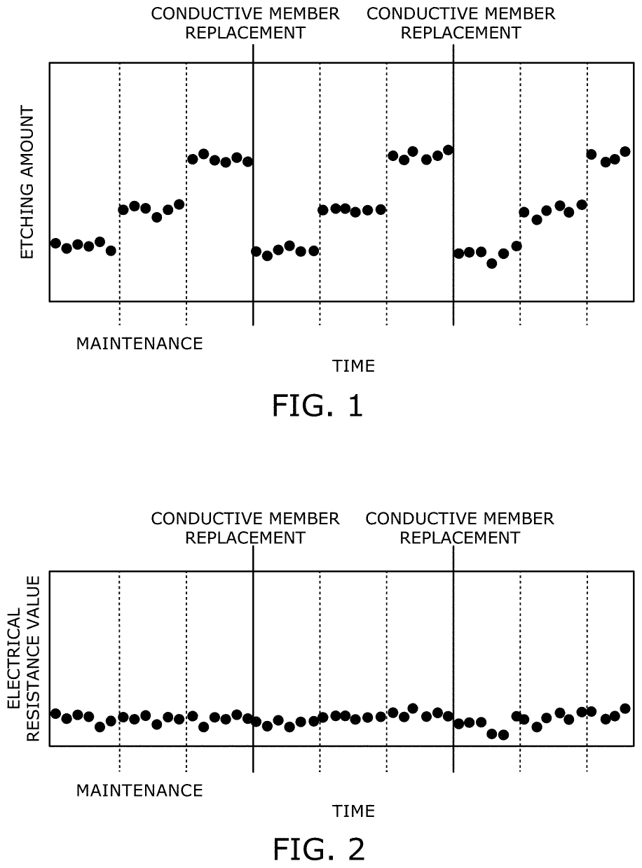

FIG. 1 is a graph showing an example of the relationship between the etching amount, the maintenance, and the part replacement of a conventional plasma etching apparatus, in which the horizontal axis is time, and the vertical axis is the etching amount.

FIG. 1 is the investigation result of one plasma etching apparatus. In FIG. 1, the broken lines that extend in the vertical direction of the illustration illustrate the timing of the maintenance; and the solid lines illustrate the timing of the replacement of the conductive member 116. This is similar for FIG. 2 described below as well.

The drawings that are attached to the specification are basically schematic views. Although made based on actual data, the drawings do not illustrate absolute values.

As shown in FIG. 1, a trend is confirmed in which the etching amount increases each time the maintenance of (6) described above is performed, and decreases after the replacement of the conductive member 116 of (7) described above. For this apparatus, the replacement interval of the conductive member 116 is greater than the interval of the maintenance; and the conductive member 116 is replaced once every few times the maintenance is performed. The results shown in FIG. 1 suggest that the maintenance and the conductive member 116 are one factor of the fluctuation of the etching rate. As described above, the conductive member 116 is a part that electrically connects the lower part 102 and the upper part 103 of the chamber 101.

Therefore, the inventors measured the electrical resistance value between the lower part 102 and the upper part 103 of the chamber 101 over a long period of time. In the specification, “electrical resistance value” means the resistance to the flow of a direct current; and “impedance” means the resistance to the flow of a high frequency current.

FIG. 2 is a graph showing an example of the relationship between the electrical resistance value and the replacement timing of the conductive member, in which the horizontal axis is time, and the vertical axis is the electrical resistance value between the lower part and the upper part of the chamber.

As shown in FIG. 2, the electrical resistance value was stable and low, and there was sufficient conduction between the lower part 102 and the upper part 103. Also, a correlation was not confirmed between the timing of the maintenance, the replacement timing of the conductive member 116, and the electrical resistance value.

The inventors formulated the following hypothesis from the investigation results described above.

It is estimated that the maintenance and the conductive member 116 affect the conditions of the etching because the etching amount discontinuously changes at the timing of the maintenance and the timing of the replacement of the conductive member 116. On the other hand, the electrical resistance value of a direct current and the impedance of a high frequency current are not always the same; and it also may be considered that the high frequency current is insufficiently conducted even when the direct current is sufficiently conducted between the lower part 102 and the upper part 103 of the chamber 101. Therefore, it is considered that the impedance increases with maintenance, even though the electrical resistance value of the conductive member 116 does not change with maintenance.

When performing the maintenance, the upper part 103 is detached from the lower part 102; and the chamber 101 is opened. Then, after performing the necessary procedures such as the repair of portions damaged by etching, etc., the upper part 103 is fixed to the lower part 102; and the chamber 101 is closed. Compression and release of the conductive member 116 is repeated each time this work is performed. Because the conductive member 116 is made of metal, the conductive member 116 elastically deforms when a compressive force is applied; however, at this time, local plastic deformation also occurs. Therefore, when the deformation of the conductive member 116 is repeated by opening and closing the chamber 101, there is a possibility that the force of the conductive member 116 pressing the lower part 102 and the upper part 103 may decrease, and the impedance to the high frequency current that is output by the high frequency power supplies 108 and 111 may increase even though the electrical resistance value of the direct current does not change.

As a result, as the plasma processing progresses, the average potential of the upper part 103 deviates from the average potential of the lower part 102; and the ground potential that is referenced by the voltage controller 107 and the ground potential from the perspective of the plasma 250 deviation. It is considered that the ground potential from the perspective of the plasma 250 is the average potential of the interior wall of the chamber 101. Therefore, even if the bias voltage is regulated according to the calibration curve shown in FIG. 31, the etching amount undesirably deviates from the calibration curve shown in FIG. 31. It is estimated that as a result, there are cases where the etching amount is excessive.

However, to verify the hypothesis described above, it is difficult to measure the ground potential from the perspective of the plasma 250; and it is also difficult to measure the impedance of the high frequency current between the lower part 102 and the upper part 103 of the chamber 101. Therefore, the relationship between the etching amount and the high frequency power (W) actually supplied to the holder 106 was measured.

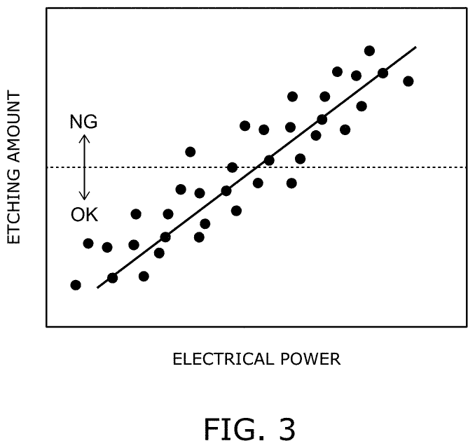

FIG. 3 is a graph showing the relationship between the supply power and the etching amount, in which the horizontal axis is the electrical power supplied to the holder, and the vertical axis is the etching amount.

As shown in FIG. 3, the etching amount has a positive correlation with respect to the input power; and when the etching was excessive, the input power also was excessive. As examined in (4) described above, it is considered unlikely that the output of the high frequency power supply 108 for applying the bias would fluctuate; therefore, it is considered that a control signal that causes a higher bias voltage than the setting value is input from the voltage controller 107 to the high frequency power supply 108.

Therefore, as in the hypothesis described above, even if the bias voltage is set according to the calibration curve that is acquired beforehand, it is estimated that the bias voltage that actually acts on the plasma 250 is different from the setting value because the ground potential that is referenced by the voltage controller 107 and the ground potential that is from the perspective of the plasma 250 are different. Also, the increase of the impedance of the conductive member 116 to the high frequency power is estimated to be a cause of the difference. It is considered that the plastic deformation of the conductive member 116 is a cause of the increase of the impedance.

Based on such estimations, an interpretation of the results shown in FIG. 1 is as follows. Namely, when the maintenance is performed, there is a tendency for the etching amount per unit time to increase because the impedance between the parts increases and the ground potential drifts. However, there is a tendency for the etching amount per unit time to return to the initial state due to the reduction of the impedance due to the replacement of the conductive member 116 mounted between the parts (referring to FIG. 30) with a new part.

Also, an interpretation of the results shown in FIG. 3 is as follows. In the plasma etching apparatus 100 shown in FIG. 29, the self-bias of the plasma is measured, and the input power is controlled so that the value of the self-bias approaches the setting value. The magnitude of the input power is shown at the horizontal axis of FIG. 3. Because the impedance between the lower part 102 and the upper part 103 of the chamber 101 changes, the ground potential that is referred to when measuring the self-bias of the plasma drifts; and an error that is dependent on the impedance occurs in the measured value of the self-bias. Therefore, an error also occurs in the input power that is controlled based on the measured value. Thus, an error that is dependent on the impedance between the lower part 102 and the upper part 103 occurs in the input power; therefore, as a result, an error also occurs in the etching amount per unit time.

### Strategy for Solving the Problem

Taking into account the examinations described above, the inventors researched a strategy for solving the problem.

To suppress the increase of the impedance to the high frequency current between the lower part 102 and the upper part 103 of the chamber 101, a new conductive member was investigated instead of the conductive member 116 in which a metal band is formed into a coil shape. For the new conductive member, it is necessary for elastic deformation to be possible, for plastic deformation substantially not to occur, and for a high frequency current to be conducted.

A resin material may be considered as a material in which elastic deformation occurs but plastic deformation does not occur. However, a resin material is not conductive as-is. Therefore, it is necessary to provide the resin material with conductivity.

As a method of providing the resin material with conductivity, a method of including a conductive particle such as carbon black, a metal filler, or the like in the resin material or a method of coating the surface with a metal may be considered. When a high frequency current is caused to flow in a conductor, the current concentrates at the surface as the frequency increases. Therefore, it is predicted that rather than including a conductive particle inside the resin material, the impedance of the high frequency current can be effectively reduced by coating the surface of the member made of the resin material with a metal. Embodiments that are described below are devised based on the examinations described above.

### First Embodiment

First, a first embodiment will be described.

Although an ICP-type plasma etching apparatus is described as the plasma processing apparatus as an example according to the embodiment, this is not limited thereto.

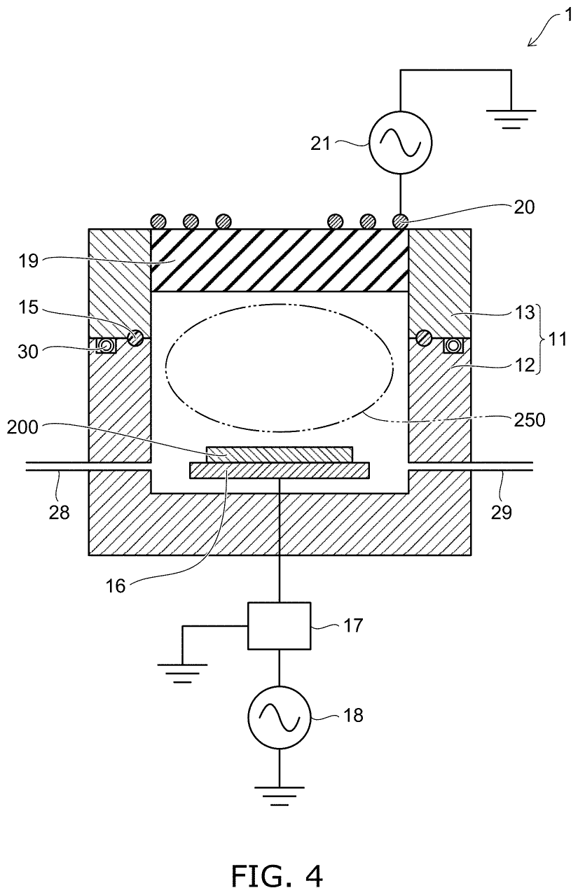

FIG. 4 is a cross-sectional view showing the plasma etching apparatus according to the embodiment.

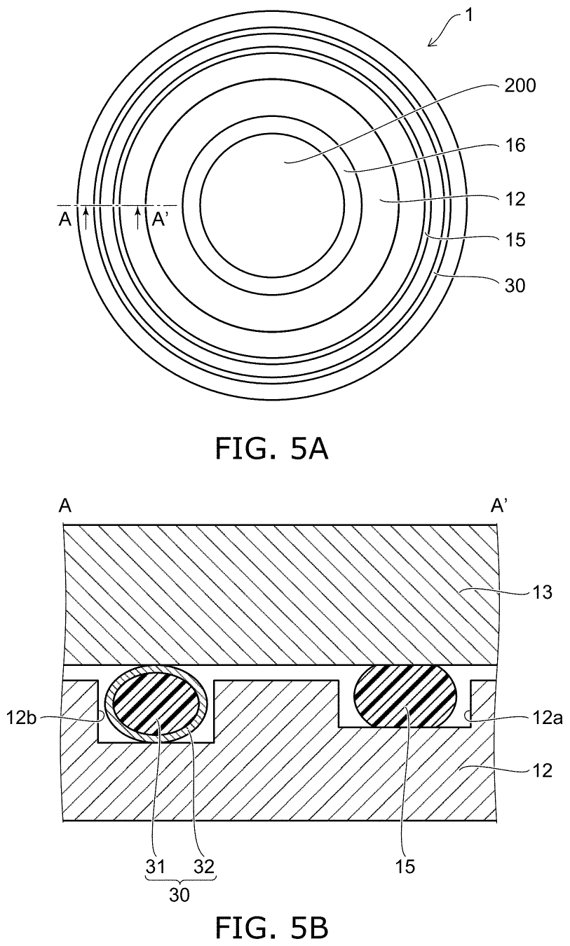

FIG. 5A is a plan view showing the lower part of the plasma etching apparatus according to the embodiment; and FIG. 5B is a cross-sectional view along line A-A′ shown in FIG. 5A.

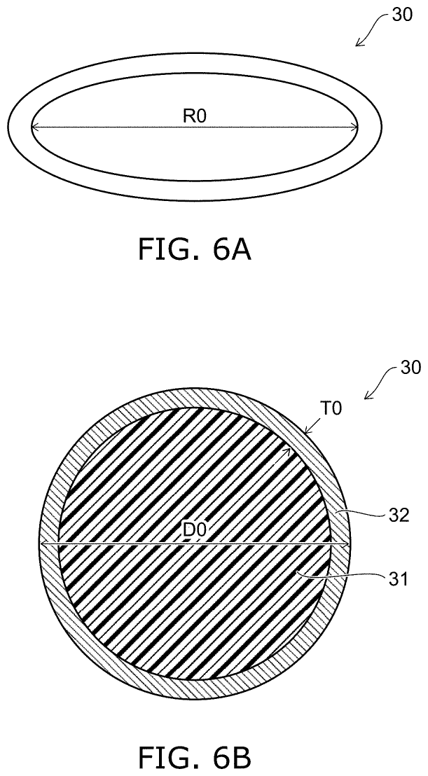

FIG. 6A is a perspective view showing the conductive member of the plasma etching apparatus according to the embodiment; and FIG. 6B is a cross-sectional view of FIG. 6A.

As shown in FIGS. 4, 5A, and 5B, a chamber 11 is provided in the plasma etching apparatus 1 according to the embodiment. A lower part 12 and an upper part 13 are provided in the chamber 11. Normally, the lower part 12 is fixed to a frame or the like and is grounded. The upper part 13 is detachably provided with respect to the lower part 12, and is not grounded. The chamber 11 is opened and closed by attaching and detaching the upper part 13 to and from the lower part 12. A slight gap exists between the lower part 12 and the upper part 13. The spacing of the gap is, for example, not more than 0.3 mm. A supply pipe 28 that supplies a gas into the chamber 11 and an exhaust pipe 29 that exhausts the gas from the interior of the chamber 11 are provided in the chamber 11.

A holder 16 is provided inside the lower part 12. The holder 16 holds the wafer 200 that is a work. The holder 16 is connected to a high frequency power supply 18 via a voltage controller 17. The voltage controller 17 and the high frequency power supply 18 each are grounded. For example, the high frequency power supply 18 outputs a high frequency current having a frequency of 13.56 MHz.

A dielectric plate 19 is provided in the upper part 13; and a coil 20 is provided on the dielectric plate 19. The coil 20 is fixed to the upper part 13. The coil 20 is connected to a high frequency power supply 21. The high frequency power supply 21 also is grounded. For example, the high frequency power supply 21 outputs a high frequency current having a frequency of 13.56 MHz.

An airtight member 15 for guaranteeing the airtightness in the chamber 11 and a conductive member 30 for guaranteeing the conduction between the lower part 12 and the upper part 13 are provided at the boundary portion between the lower part 12 and the upper part 13. In other words, a groove 12a that is circular-ring-shaped is formed in the upper surface of the lower part 12; and a groove 12b that is circular-ring-shaped is formed at the outer side of the groove 12a. Then, the airtight member 15 is disposed in the groove 12a. The airtight member 15 is, for example, an O-ring. The conductive member 30 is disposed in the groove 12b. Thus, the conductive member 30 is disposed outward of the airtight member 15. Also, the lower part 12 and the upper part 13 are coupled by bolts and nuts that are made of metal. The lower part 12 and the upper part 13 are mechanically coupled thereby, and the airtight member 15 and the conductive member 30 are pressed by the lower part 12 and the upper part 13.

As shown in FIGS. 6A and 6B, the overall shape of the conductive member 30 of the embodiment is ring-shaped. In the conductive member 30, a metal film 32 that is made of a metal material covers the entire surface of a resin ring 31 that is made of a resin material. A ring diameter R0 of the conductive member 30 is dependent on the outer diameter of the chamber 11; however, for example, the ring diameter R0 is about 600 mm when the diameter of the wafer 200 is 300 mm (millimeters). A diameter D0 of the conductive member 30 is, for example, about 2 to 4 mm (millimeters). A film thickness T0 of the metal film 32 is, for example, not less than 200 nm (nanometers). For example, it is favorable for the maximum diameter in the compressive direction to be not less than 2 mm and not more than 4 mm when the conductive member 30 is compressed so that the compression ratio is in the range of not less than 5% and not more than 25%.

The resin material that forms the resin ring 31 is, for example, elastic rubber, e.g., fluororubber, e.g., FKM-70. The elastic modulus of the resin ring 31 is, for example, 10 MPa. The diameter of the resin ring 31 is, for example, 3 mm; and Poisson's ratio is about 0.5. The film configuration of the metal film 32 may be, for example, a single-layer film made of nickel (Ni) or copper (Cu), or may be a multilayer film in which two or more layers are stacked.

For example, the metal film 32 can be adhered over the surface of the resin ring 31 by an intermolecular adhesive bond. Specifically, after the resin ring 31 is formed, corona discharge processing of the resin ring 31 is performed, and OH groups are generated at the surface. Then, the resin ring 31 is caused to contact alkoxysilylpropylamide triazine thiol; and dithiol triazine groups are generated at the surface. Then, the resin ring 31 is dipped in a plating liquid. Thereby, the metal ions in the plating liquid are chemically bonded with the dithiol triazine groups; and the metal film 32 is formed. Thereby, a high adhesion force can be realized between the resin ring 31 and the metal film 32.

Operations of the plasma processing apparatus according to the embodiment, i.e., the plasma processing method according to the embodiment, will now be described.

As shown in FIG. 4, when performing maintenance of the interior of the chamber 11, the chamber 11 is opened by detaching the upper part 13 from the lower part 12. At this time, the compressive force that was applied to the conductive member 30 is released. The necessary maintenance is performed in this state. After the maintenance has ended, the upper part 13 is coupled to the lower part 12 in a state in which the airtight member 15 is disposed in the groove 12a of the lower part 12 and the conductive member 30 is disposed in the groove 12b. The conductive member 30 is compressed thereby.

When performing plasma etching of the wafer 200, the wafer 200 is mounted to the holder 16 via a load lock part of the chamber 11. Then, the interior of the chamber 11 is exhausted via the exhaust pipe 29; and the gas that is used to form the plasma species is introduced via the supply pipe 28. In this state, the high frequency power supply 21 supplies a high frequency current to the coil 20. The gas is ionized thereby, and the plasma 250 is formed. Also, the high frequency power supply 18 supplies a high frequency current to the holder 16. Thereby, a bias voltage is applied to the plasma 250; and the ions in the plasma are accelerated and collide with the wafer 200. As a result, the wafer 200 is etched. At this time, a high frequency current is conducted via the conductive member 30 between the lower part 12 and the upper part 13.

When the upper part 13 is coupled to the lower part 12, pressure is applied to the resin ring 31 in the vertical direction; and the resin ring 31 elastically deforms. The metal film 32 also deforms according to the elastic deformation of the resin ring 31. The metal film 32 is pressed onto the lower part 12 and the upper part 13 by the elastic force of the resin ring 31. Then, the high frequency currents that are output by the high frequency power supplies 18 and 21 are conducted between the lower part 12 and the upper part 13 via the metal film 32. As a result, the difference between the average potential of the lower part 12 and the average potential of the upper part 13 becomes small, and the difference between the ground potential referenced by the voltage controller 17 and the ground potential from the perspective of the plasma 250 becomes small. On the other hand, when the chamber 11 is opened, that is, when the upper part 13 is detached from the lower part 12, the shape of the resin ring 31 returns to the original because the pressure that was applied to the resin ring 31 is released. At this time, the shape of the metal film 32 also returns to the original.

Thus, even when the compressive force is repeatedly applied to the resin ring 31, the resin ring 31 is formed of a resin material and therefore does not plastically deform. Therefore, the force of pressing the metal film 32 onto the lower part 12 and the upper part 13 is not reduced by plastic deformation. The increase of the impedance of the metal film 32 can be suppressed thereby.

Although there is also a possibility that the metal film 32 may plastically deform with the deformation of the resin ring 31 described above, the force of pressing the metal film 32 onto the lower part 12 and the upper part 13 is caused by the elastic force of the resin ring 31 and not by the metal film 32 itself. Therefore, even when the metal film 32 plastically deforms, the pressing force does not change, and the impedance that is caused by the plastic deformation of the metal film 32 is not greatly increased. Also, the resin ring 31 that is insulative occupies the greater part of the volume of the conductive member 30; therefore, there are cases where the electrical resistance value of the conductive member 30 to the direct current is greater than the electrical resistance value of the conventional conductive member 116 shown in FIG. 30. However, as described above, the high frequency current concentrates at the surface layer portion of the conductive member 30; and the metal film 32 is disposed at this portion; therefore, the impedance to the high frequency current is sufficiently low.

Effects of the embodiment will now be described.

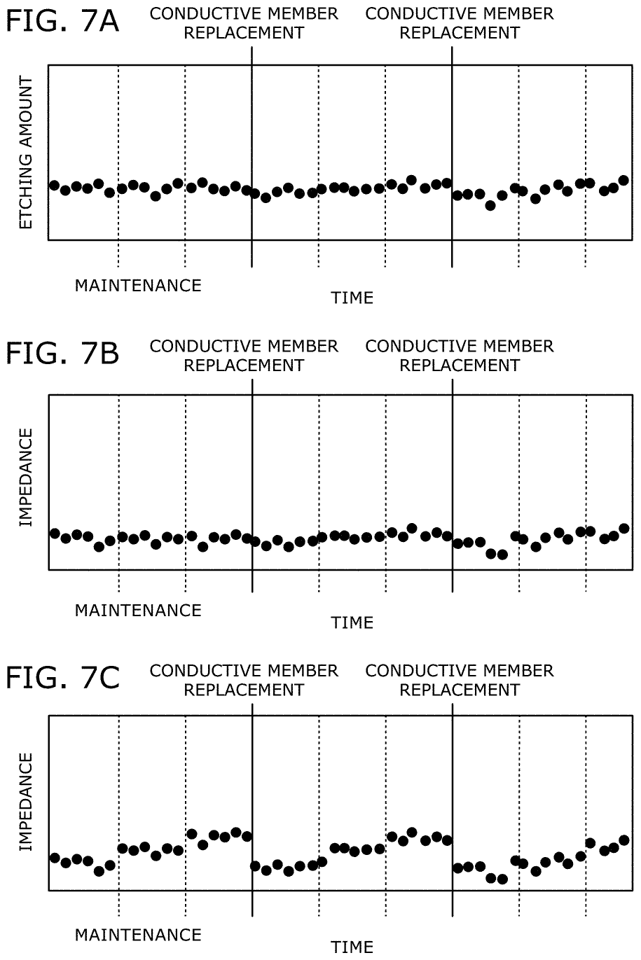

FIG. 7A is a graph showing an example of the relationship between the etching amount, the maintenance, and the part replacement of the plasma etching apparatus according to the embodiment, in which the horizontal axis is time, and the vertical axis is the etching amount; FIG. 7B is a graph showing an example of the relationship between the impedance, the maintenance, and the part replacement of the plasma etching apparatus according to the first embodiment, in which the horizontal axis is time, and the vertical axis is the impedance; and FIG. 7C is a graph showing an example of the relationship between the impedance, the maintenance, and the part replacement of a plasma etching apparatus according to a comparative example, in which the horizontal axis is time, and the vertical axis is the impedance.

According to the embodiment as shown in FIG. 7A, even when the maintenance and the replacement of the conductive member 30 were performed, the etching amount did not greatly change, and a stable operation was possible. Also, according to the embodiment as shown in FIG. 7B, even when the maintenance and the replacement of the conductive member 30 were performed, the change of the impedance between the lower part 12 and the upper part 13 was small, which suggests that a stable operation is possible.

On the other hand, the impedance between the lower part 102 and the upper part 103 was also measured for the plasma etching apparatus 100 according to the comparative example shown in FIG. 29. As a result, for the plasma etching apparatus 100 according to the comparative example as shown in FIG. 7C, by performing the maintenance, the impedance between the lower part 102 and the upper part 103 becomes large after maintenance due to the deformation of the conductive member 116 (referring to FIG. 30), etc. However, a tendency for the impedance to be returned to the initial value by replacing the conductive member 116 with a new part was confirmed. A one-to-one correlation between the change of the impedance and the etching amount per unit time was confirmed.

Thus, according to the embodiment, the resin ring 31 that is made of a resin material, e.g., an elastic rubber, and the metal film 32 that covers the surface of the resin ring 31 are provided in the conductive member 30; therefore, the elastic force of the resin ring 31 does not decrease even when repeatedly opening and closing the chamber 11. Therefore, the increase of the impedance between the lower part 12 and the upper part 13 can be suppressed, and the deviation of the etching rate can be suppressed. As a result, the plasma etching can be stably performed.

Also, because the greater part of the volume of the conductive member 30 is formed of the resin ring 31, the conductive member 30 is soft as an entirety. Therefore, compared to the conductive member 116 that is made of a metal band, the mounting into the recess 12b of the lower part 12 is easy.

### <Investigation for Mounting>

Actual design of the plasma etching apparatus 1 according to the embodiment will now be investigated.

When actually designing the plasma etching apparatus 1 according to the embodiment, the dimensions of the parts, etc., are different according to the necessary specifications; therefore, how to design the plasma etching apparatus 1 that includes the conductive member 30 is problematic. The ring diameter R0 of the conductive member 30 is determined according to the size of the chamber 11; and the size of the chamber 11 is determined by the size of the wafer 200 that is the work. On the other hand, the diameter D0 of the conductive member 30 is determined by considering the compression ratio.

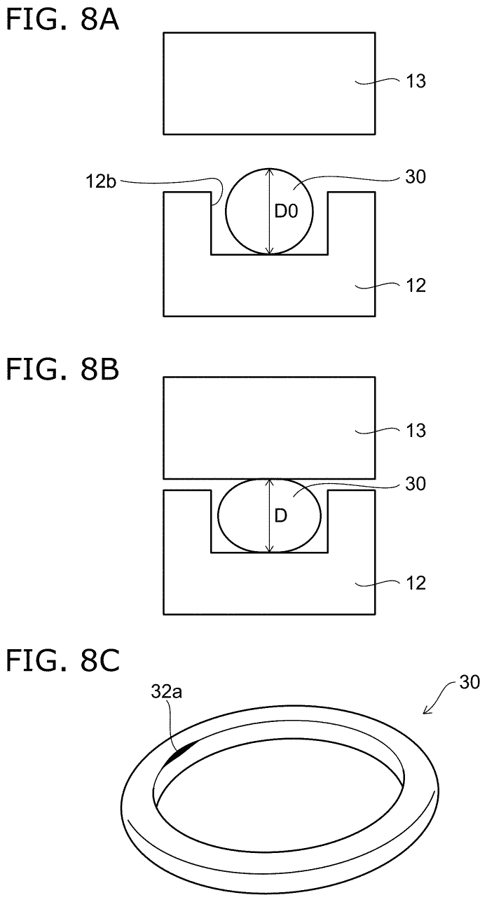

FIG. 8A is a cross-sectional view showing the shape of the conductive member 30 when the chamber is opened; FIG. 8B is a cross-sectional view showing the shape of the conductive member 30 when the chamber is sealed; and FIG. 8C is a photograph showing the conductive member 30 in a state in which a crack has occurred in the metal film 32.

A compression ratio C is defined as in Formula 1 described below, in which the diameter of the conductive member 30 when the chamber 11 is opened and an external force is not applied to the conductive member 30 as shown in FIG. 8A is D0, and the diameter of the conductive member 30 when the chamber 11 is sealed as shown in FIG. 8B is D.

C=(D0−D)/D0×100(%) (Formula 1)

As shown in FIG. 8C, a crack 32a occurs in the metal film 32 of the conductive member 30 when the compression ratio C exceeds a prescribed value. When the crack 32a occurs, the likelihood of the impedance to the high frequency current markedly increasing is high. Therefore, it is favorable for the conductive member 30 to be used to have the compression ratio C such that the crack 32a does not occur in the metal film 32.

An experimental example that determines the range of the compression ratio C such that the crack 32a does not occur will now be described.

In the experimental example, a compressive force is repeatedly applied to the conductive member 30 while changing the compression ratio; and the electrical resistance value of the conductive member 30 is measured each compression and release. The electrical resistance value of the conductive member 30 greatly increases irreversibly when a large crack 32a occurs in the metal film 32.

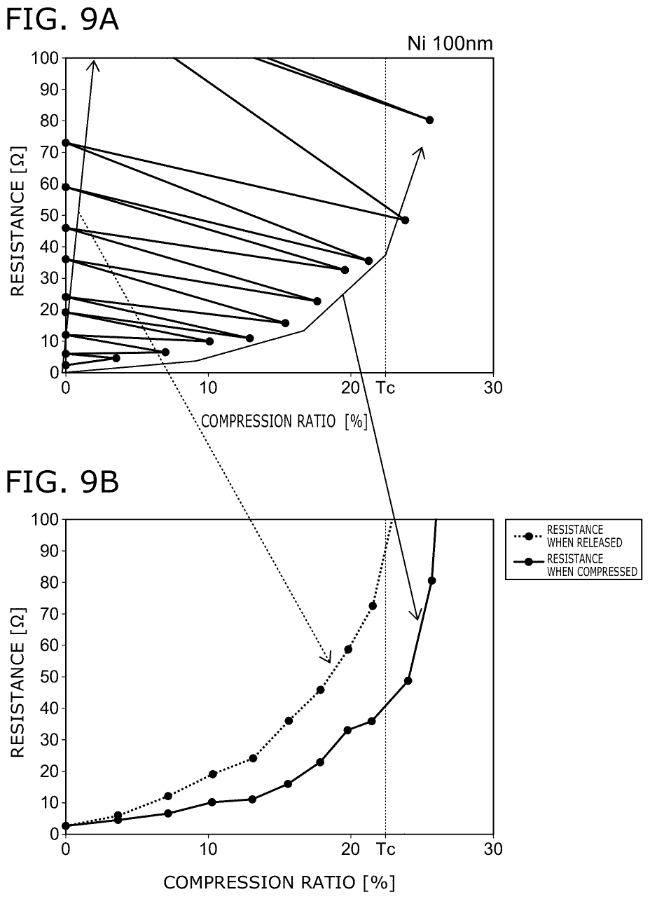

FIG. 9A is a graph showing the change of the resistance value when repeatedly applying a compressive force to the conductive member in which the metal film 32 is made of nickel and has a thickness of 100 nm while changing the compression ratio, in which the horizontal axis is the compression ratio, and the vertical axis is the electrical resistance value; and FIG. 9B is a graph of the data shown in FIG. 9A that shows the effects of the compression ratio on the electrical resistance value, in which the horizontal axis is the compression ratio when compressed, and the vertical axis is the electrical resistance value when compressed and when released.

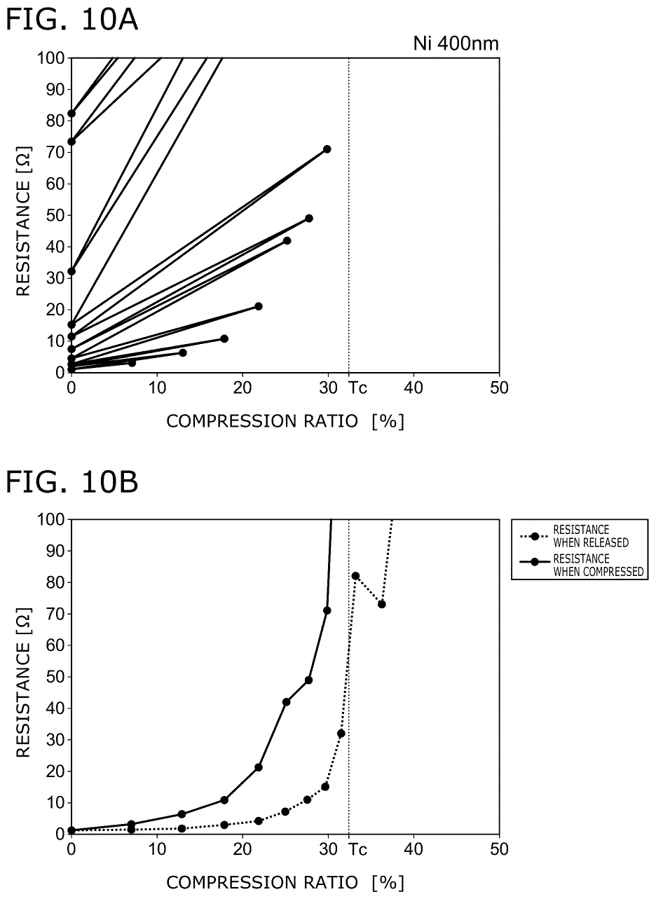

FIGS. 10A to 14B also are graphs similar to FIGS. 9A and 9B.

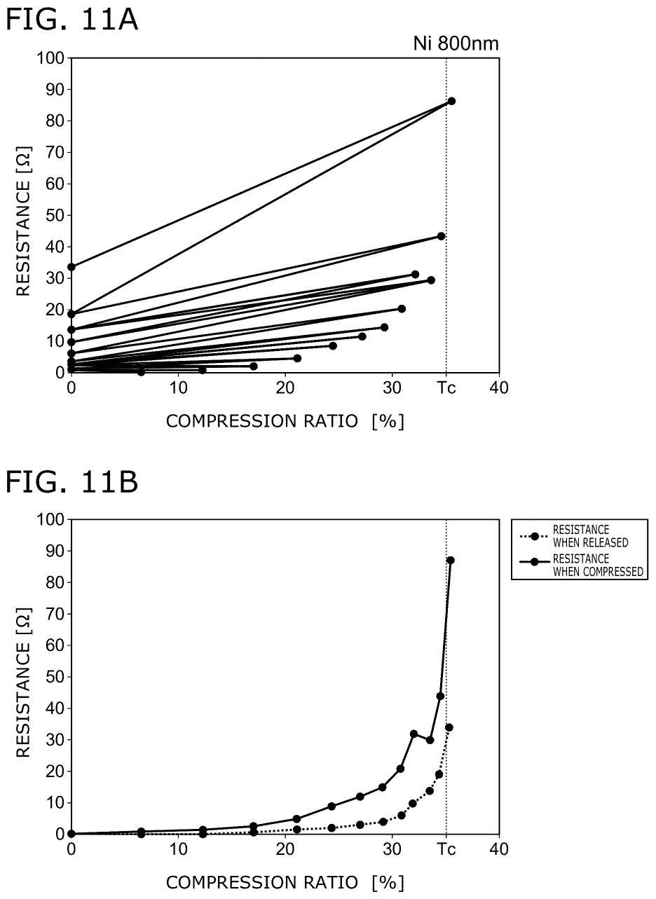

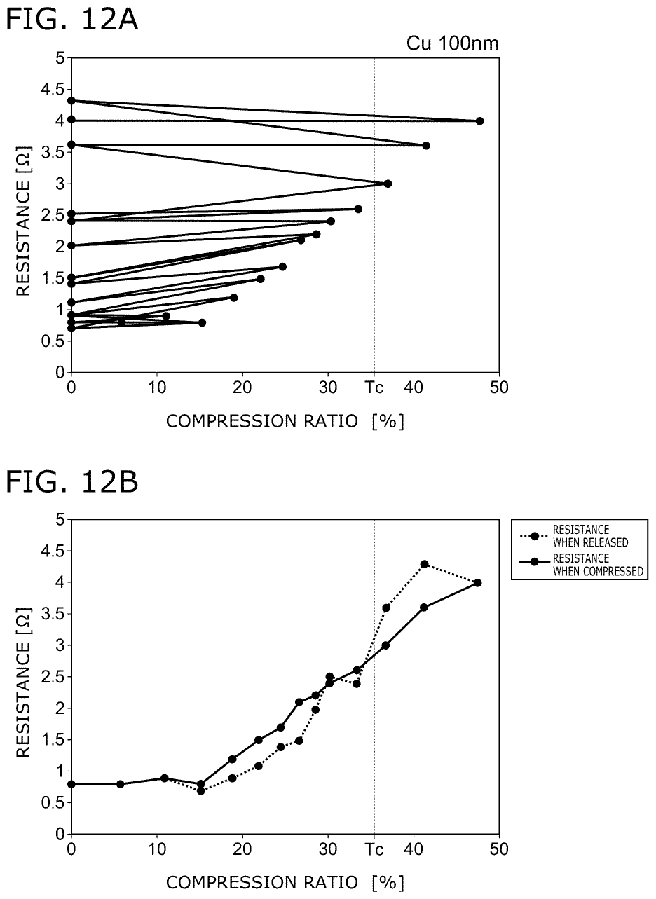

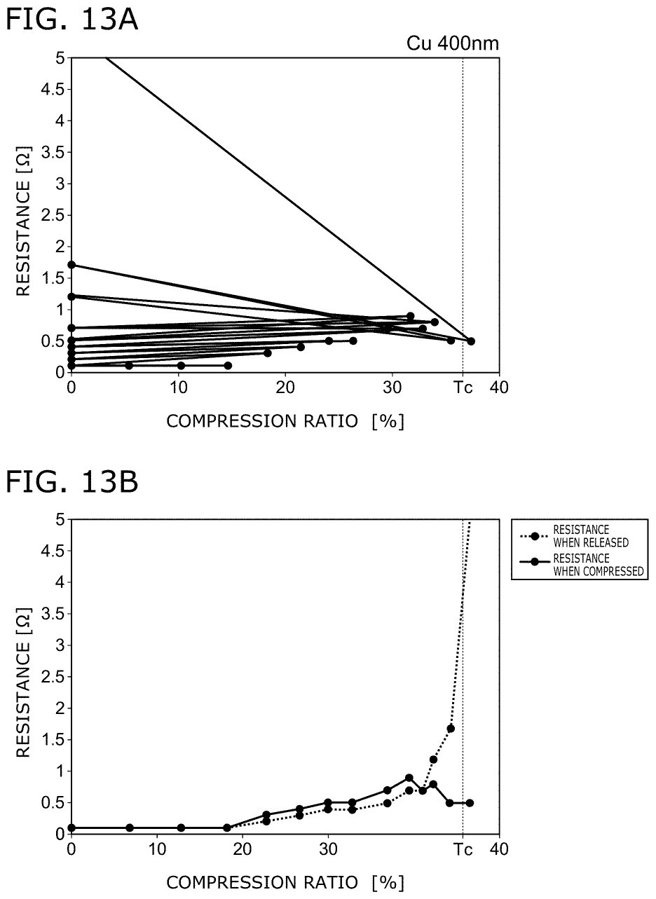

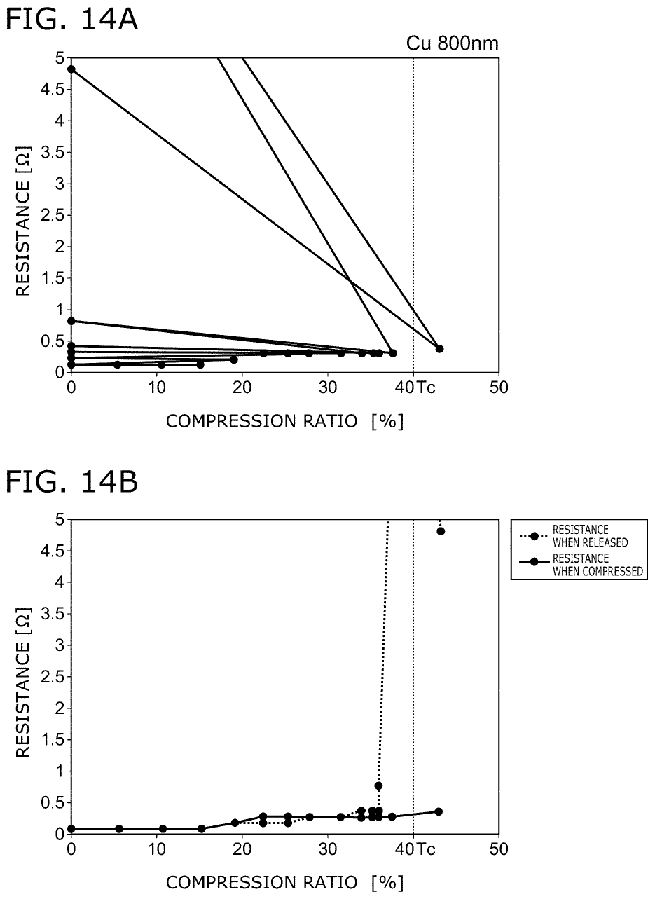

FIGS. 10A and 1013 show the case where the metal film 32 is made of nickel and has a thickness of 400 nm; FIGS. 11A and 11B show the case where the metal film 32 is made of nickel and has a thickness of 800 nm; FIGS. 12A and 12B show the case where the metal film 32 is made of copper and has a thickness of 100 nm; FIGS. 13A and 13B show the case where the metal film 32 is made of copper and has a thickness of 400 nm; and FIGS. 14A and 14B show the case where the metal film 32 is made of copper and has a thickness of 800 nm.

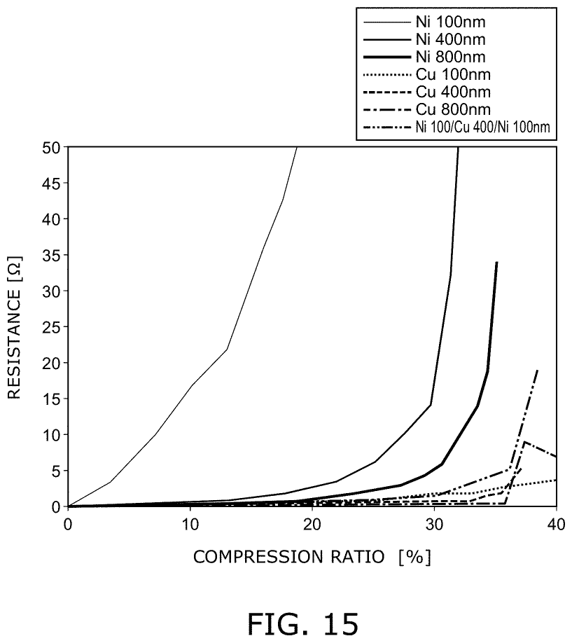

FIG. 15 is a graph showing the effect of the composition and film thickness of the metal film on the relationship between the compression ratio and the electrical resistance value, in which the horizontal axis is the compression ratio when compressed, and the vertical axis is the electrical resistance value when released.

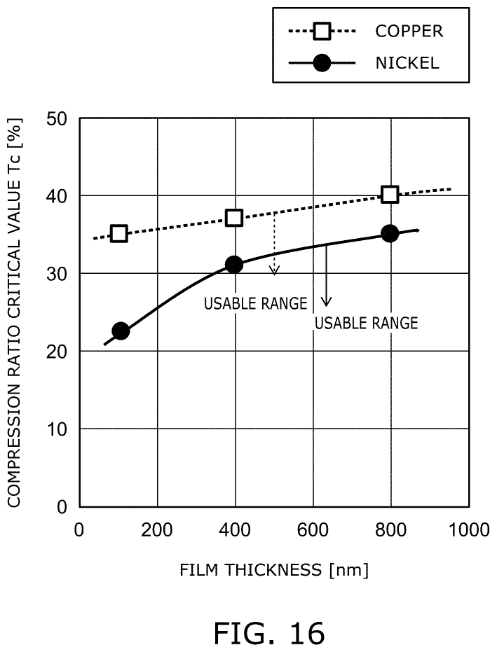

FIG. 16 is a graph showing the favorable range of use of the conductive member, in which the horizontal axis is the film thickness of the metal film, and the vertical axis is the compression ratio directly before the resistance value undergoes an irreversible change.

As shown in FIGS. 9A to 14B, when the metal film 32 is made of nickel or copper and the film thickness is in the range of 100 nm to 800 nm, and when the compressing and releasing is repeated while increasing the compression ratio, the electrical resistance value gradually increases; the existence of a critical value Tc is confirmed; and when the compression ratio is compressed to exceed the critical value Tc, the electrical resistance value drastically increases when released the next time. It is considered that a large crack 32a occurs in the metal film 32 when compressed to the critical value Tc and subsequently released.

As shown in FIGS. 15 and 16, for the same film thickness, the resistance to compression is higher when the metal film 32 is formed of copper than when formed of nickel. Also, for the same metal film 32 material, the resistance to compression is higher when the film thickness is thick.

Thus, by determining the critical value Tc of the compression ratio according to the composition and film thickness of the metal film 32, the range of compression ratio in which the conductive member 30 is repeatedly usable can be determined as shown in FIG. 16. As a result, the relationship between the diameter D0 of the conductive member 30 and the depth of the groove 12b formed in the lower part 12 can be determined.

For example, when the metal film 32 is made of nickel and has a film thickness of not less than 200 nm, it is favorable for the compression ratio to be not more than 25%; when the film thickness is not less than 400 nm, it is favorable for the compression ratio to be not more than 30%; and when the film thickness is not less than 800 nm, it is favorable for the compression ratio to be not more than 35%. Also, when the metal film 32 is made of copper and has a film thickness of not less than 200 nm, it is favorable for the compression ratio to be not more than 35%. On the other hand, to suppress the impedance to be sufficiently low, it is favorable for the compression ratio to be not less than 5%. For example, it is favorable for the film thickness of the metal film 32 to be not less than 100 nm and not more than 2000 nm, and more favorable to be not less than 100 nm and not more than 1000 nm.

The material of the metal film 32 is not limited to nickel and copper. For example, at least one type of metal selected from the group consisting of nickel (Ni), chrome (Cr), titanium (Ti), tungsten (W), cobalt (Co), gold (Au), silver (Ag), copper (Cu), tin (Sn), and zinc (Zn) may be used as the material of the metal film 32.

Also, the metal film 32 may be a multilayer film. For example, the metal film 32 may be a three-layer film made of a foundation layer, a major layer, and a surface layer in this order from the resin ring 31 side. In such a case, for example, a material that has a dense crystal structure and high chemical stability, e.g., nickel may be used as the material of the foundation layer; a material that has excellent ductility, e.g., copper may be used as the material of the major layer; and a material that has excellent chemical stability and conductivity, e.g., gold may be used as the material of the surface layer. In other words, the metal film 32 may be a (Ni/Cu/Au) three-layer film. By forming the foundation layer of nickel, the diffusion of the copper of the major layer into the resin ring 31 and the degradation of the resin ring 31 due to copper damage can be suppressed. Also, by forming the major layer of copper, the occurrence of the crack 32a in the metal film 32 can be suppressed. Also, by forming the surface layer of gold, the oxidization of the copper in the major layer by ambient air can be suppressed. Or, the foundation layer and the surface layer may be formed of nickel; and the major layer may be formed of copper. In other words, the metal film 32 may be a (Ni/Cu/Ni) three-layer film. In such a case, for example, the thicknesses of the foundation layer and the surface layer each may be 100 nm; and the thickness of the major layer may be 400 nm.

### Second Embodiment

A second embodiment will now be described.

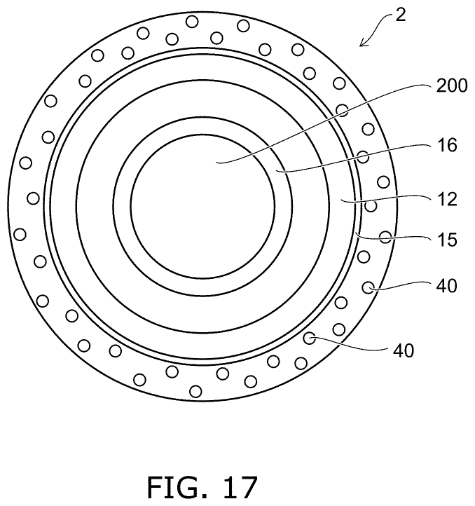

FIG. 17 is a plan view showing the lower part of a plasma etching apparatus according to the embodiment.

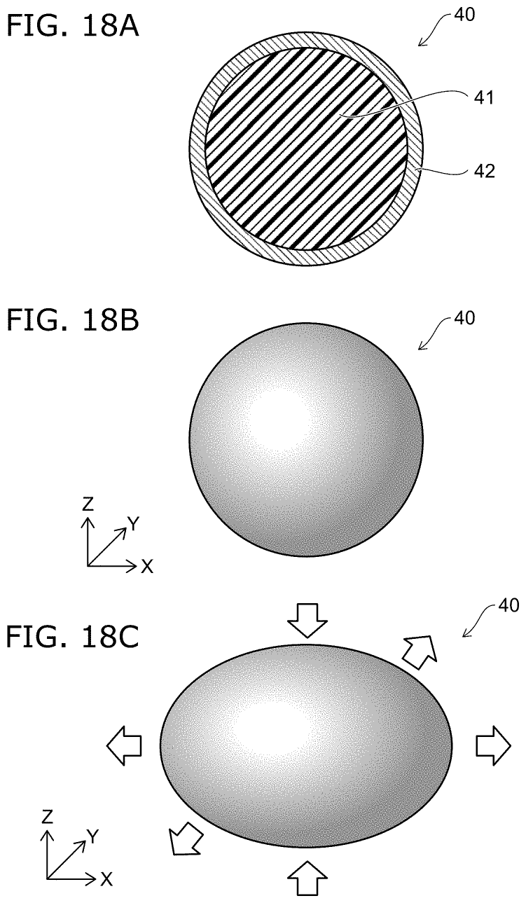

FIG. 18A is a cross-sectional view showing a conductive member of the plasma etching apparatus according to the embodiment; FIG. 18B is a perspective view showing the conductive member in the released state; and FIG. 18C is a perspective view showing the conductive member in the compressed state.

In the plasma etching apparatus 2 according to the embodiment as shown in FIG. 17, multiple conductive members 40 are provided at the periphery of the airtight member 15.

As shown in FIG. 17 and FIGS. 18A and 18B, the shape of each conductive member 40 is spherical instead of circular-ring-shaped. For example, a circular tubular recess is formed in the upper surface of the lower part 12 of the chamber 11; and the conductive member 40 is housed in the recess. A resin sphere 41 that is made of a resin material, e.g., elastic rubber, e.g., fluororubber is provided in each conductive member 40; and a metal film 42 covers the surface of the resin sphere 41. The composition and film thickness of the metal film 42 are similar to those of the metal film 32 according to the first embodiment.

In the plasma etching apparatus 2, the airtightness of the chamber 11 is realized by the airtight member 15; therefore, the conductive member 40 may not always be ring-shaped. As in the embodiment, a clump-shaped, e.g., spherical conductive member 40 may be provided. Also, by providing multiple conductive members 40, a low impedance can be realized in the parts of the chamber 11.

Also, because the conductive member 40 is spherical as shown in FIGS. 18B and 18C, the conductive member 40 can elongate in the other two axis directions, e.g., an X-axis direction and a Y-axis direction when compressed in one axis direction, e.g., a Z-axis direction shown in FIGS. 18B and 18C. Thereby, the elongation percentage per axis becomes small; and the mechanical stress that is applied to the metal film 42 is dispersed. As a result, the metal film 42 can withstand a higher compression ratio. Therefore, the conductive member 40 can be used with a higher compression ratio; and the impedance can be more reliably reduced.

However, it is favorable for the shape of the conductive member 40 to satisfy Formula 2 described below. Formula 2 described below is an inequality formula of Euler's formula. By satisfying Formula 2 described below, buckling of the conductive member 40 can be reliably avoided. In Formula 2 described below, P is the load applied to the conductive member 40; P_{cr} is the buckling load of the conductive member 40; C is the end fixity coefficient; π is pi; E is Young's modulus; I is the moment of inertia of area; and L is the length.

P<P_{cr}=Cπ²EI/L² (Formula 2)

Otherwise, the configuration, the operations, and the effects according to the embodiment are similar to those of the first embodiment described above.

Although an example is shown in the embodiments described above in which the conductive member is disposed between the lower part 12 and the upper part 13 of the chamber 11, this is not limited thereto. The conductive member described in the embodiments described above can be interposed between any portion of the plasma processing apparatus that is proximate to the plasma and is insufficiently electrically connected to another member such as in a load lock portion for loading and unloading the wafer 200, in the joint of a flange, etc.

Also, although the plasma etching apparatus is described in the embodiments described above as an example of the plasma processing apparatus, the plasma processing apparatus is not limited to an etching apparatus and may be, for example, a film formation apparatus such as a plasma CVD (Chemical Vapor Deposition: chemical vapor deposition) apparatus, etc.

According to embodiments described above, a plasma processing apparatus, a plasma processing method, and a conductive member that have stable operations can be realized.

### Test Example

A test example will now be described.

In the test example, the plasma etching apparatus 1 according to the first embodiment shown in FIG. 4, FIGS. 5A and 5B, and FIGS. 6A and 6B was actually made, and is called the “example”. Here, the material of the metal film 32 of the conductive member 30 was nickel and had a thickness of 400 nm.

On the other hand, the general plasma etching apparatus 100 shown in FIGS. 29 and 30 was actually made, and is called the “comparative example”. Then, etching of a test member was performed using the apparatus according to the example and the apparatus according to the comparative example; and the distribution of the etching rate in the test member was measured.

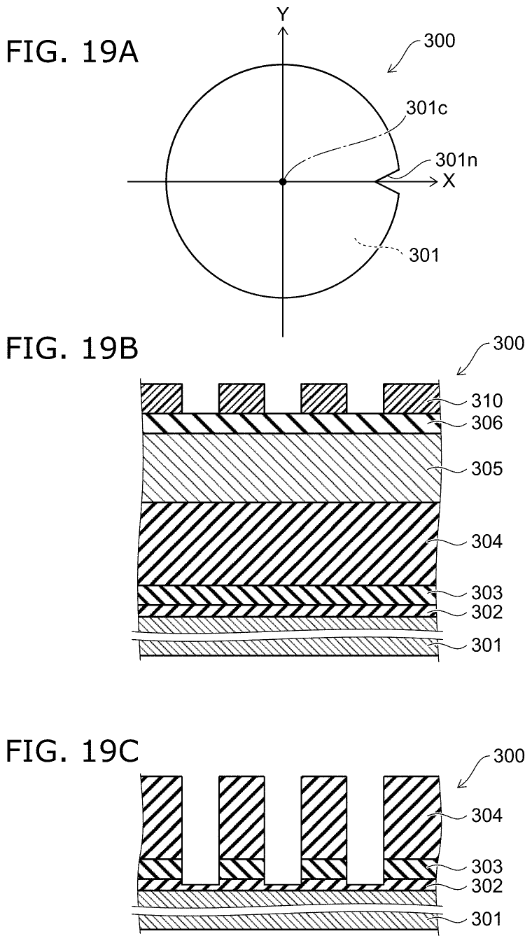

FIG. 19A is a plan view showing the test member used as the etching object of the test example; FIG. 19B is a cross-sectional view showing the test member before the etching; and FIG. 19C is a cross-sectional view showing the test member after the etching.

As shown in FIGS. 19A to 19C, a silicon wafer 301 is provided in the test member 300 that is used in the test example. A notch 301n is formed in the silicon wafer 301. Among directions parallel to the upper surface of the silicon wafer 301, the direction from a center 301c of the silicon wafer 301 toward the notch 301n is taken as the “X-direction”; and a direction orthogonal to the X-direction is taken as the “Y-direction”.

In the test member 300, the following films are stacked in this order on the silicon wafer 301. The numerical values inside the parentheses show the thicknesses of the films.
Silicon oxide film 302 (10 nm)
Silicon nitride film 303 (20 nm)
Silicon oxide film 304 (500 nm)
Carbon film 305 (500 nm)
Silicon oxide film 306 (50 nm)
Resist pattern 310 (100 nm)

The silicon oxide film 304 was formed by CVD using TEOS (Tetraethyl orthosilicate: tetraethyl orthosilicate: Si(OC₂H₅)₄) as a raw material. The silicon oxide film 306 was formed by coating. A prescribed pattern was formed in the resist pattern 310 by lithography.

Two of the test members 300 were made; and RIE (Reactive Ion Etching) was performed using the plasma etching apparatuses according to the example and the comparative example. The etching conditions were adjusted according to the films used as the etching object, but were the same between the example and the comparative example.

First, the silicon oxide film 306 was patterned by etching the silicon oxide film 306 using the resist pattern 310 as a mask. Subsequently, the resist pattern 310 was removed.

Then, the carbon film 305 was patterned by etching the carbon film 305 using the patterned silicon oxide film 306 as a mask. The etching rate distribution of the carbon film 305 in the surface of the test member 300 was measured at this time.

Then, the silicon oxide film 304 was patterned by etching the silicon oxide film 304 using the patterned carbon film 305 as a mask. The etching rate distribution of the silicon oxide film 304 in the surface of the test member 300 was measured at this time. Subsequently, the residue that occurred due to the etching of the silicon oxide film 304 was removed.

Then, the silicon nitride film 303 was patterned by etching the silicon nitride film 303 using the patterned carbon film 305 and silicon oxide film 304 as a mask. The etching rate distribution of the silicon nitride film 303 in the surface of the test member 300 was measured at this time.

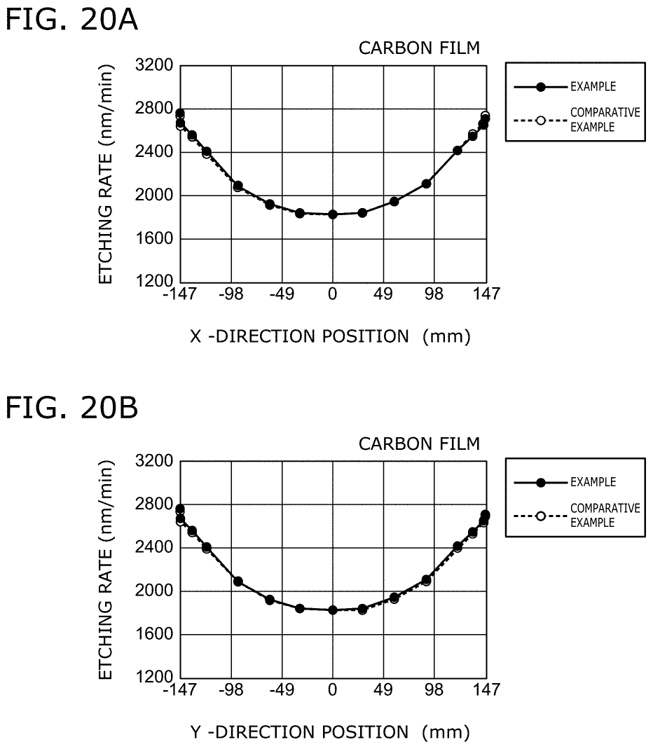

FIGS. 20A and 20B are graphs showing the etching rate distribution for the carbon film 305, in which the horizontal axis is the position, and the vertical axis is the etching rate.

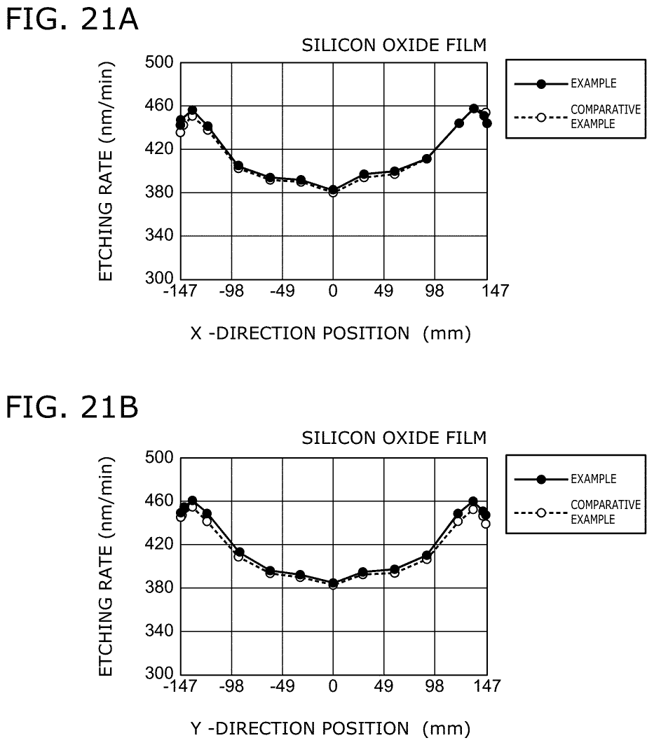

FIGS. 21A and 21B are graphs showing the etching rate distribution for the silicon oxide film 304, in which the horizontal axis is the position, and the vertical axis is the etching rate.

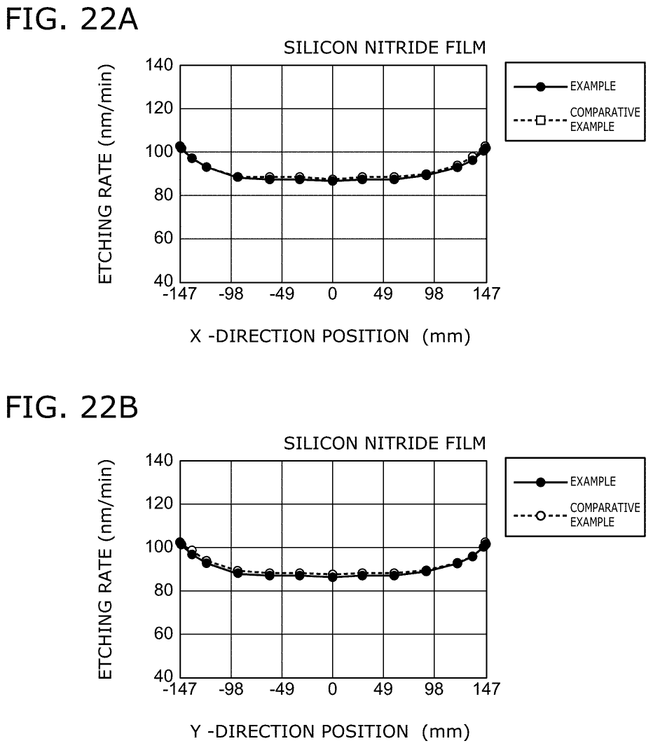

FIGS. 22A and 22B are graphs showing the etching rate distribution for the silicon nitride film 303, in which the horizontal axis is the position, and the vertical axis is the etching rate.

In the figures, the horizontal axis is the position in the X-direction or the Y-direction of the silicon wafer 301; and the position of the center 301c is “0”.

As shown in FIGS. 20A to 22B, the etching rate has a distribution in the surface of the test member 300; and the etching rate and the distribution of the etching rate are substantially the same between the example and the comparative example. Therefore, it was found that the use can be continued even when a conventional plasma etching apparatus is replaced with the plasma etching apparatus according to the first embodiment because it is unnecessary to readjust the etching conditions.

In the plasma etching apparatus 1 according to the example, there was a risk of contamination of the interior of the apparatus by nickel because the metal film 32 of the conductive member 30 was formed of nickel. Therefore, the nickel amount of the test member 300 after the etching was measured.

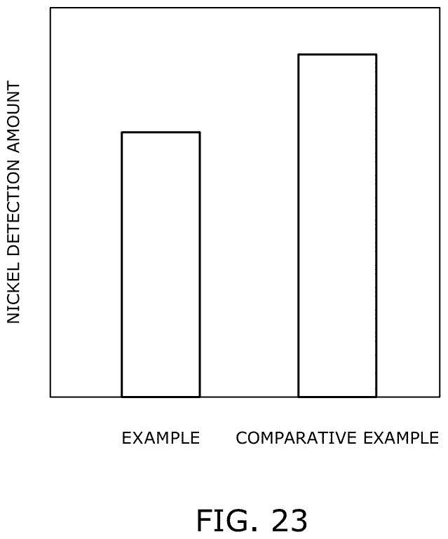

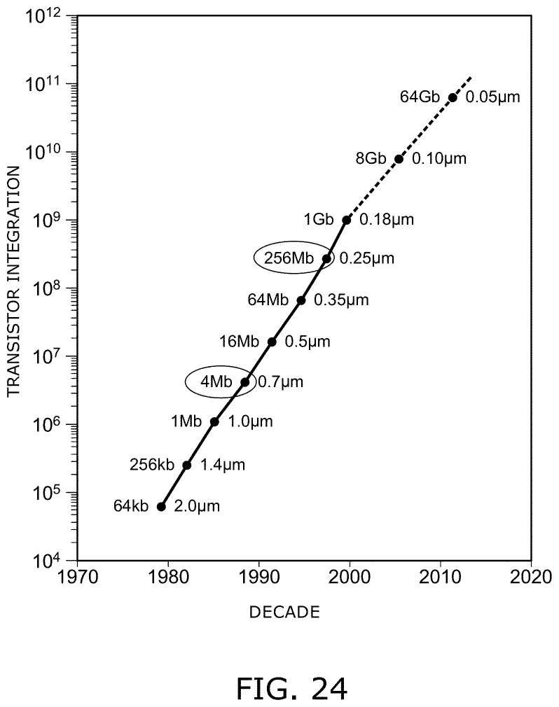

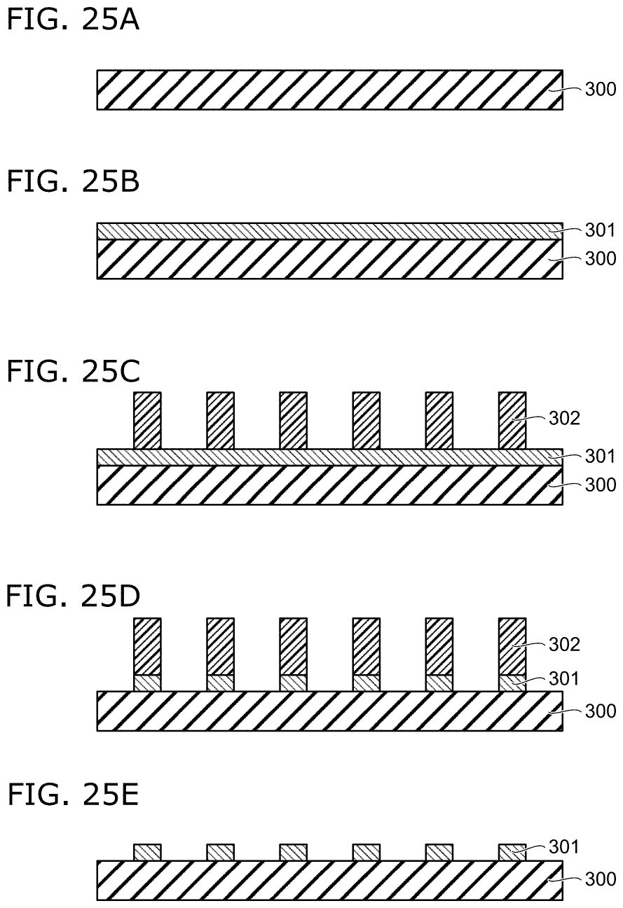

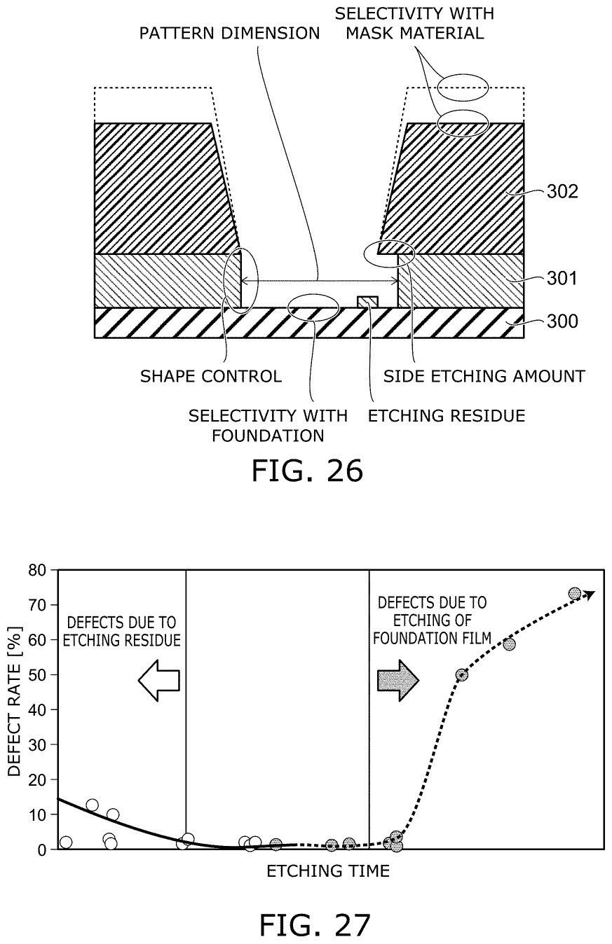

FIG. 23 is a graph showing the existence or absence of nickel contamination, in which the horizontal axis is the sample, and the vertical axis is the nickel detection amount of the test member after the etching.

As shown in FIG. 23, the detection amount of nickel according to the example was equal to or less than that of the nickel detection amount of the comparative example. Therefore, it can be said that nickel contamination that is caused by the conductive member 30 did not occur. Also, the generation amount of dust of the example was equal to or less than that of the comparative example, and satisfied the existing standard.

Thus, compared to the plasma etching apparatus 100 according to the comparative example, the plasma etching apparatus 1 according to the example has substantially the same etching rate and distribution of the etching rate; contamination that is caused by the conductive member 30 was not confirmed; and the generation amount of dust did not increase. Thereby, it was confirmed that there is no problem even when replacing a conventional plasma etching apparatus with the plasma etching apparatus according to the first embodiment. For example, the plasma etching apparatus 1 can be inexpensively realized by replacing the conductive member 116 with the conductive member 30 (referring to FIGS. 6A and 6B) in the plasma etching apparatus 100 shown in FIG. 29.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A plasma processing apparatus, comprising:
a chamber including a first member, and
a second member detachable from the first member;
a conductive member disposed between the first member and the second member; and
a first high frequency power supply generating plasma in the chamber,
the conductive member including
a resin member made of a resin material, and
a metal film covering a surface of the resin member.

2. The plasma processing apparatus according to claim 1, wherein
a gap is formed between the first member and the second member.

3. The plasma processing apparatus according to claim 1, wherein
the second member is not grounded.

4. The plasma processing apparatus according to claim 1, further comprising:
a holder located in the chamber, the holder holding a work; and
a second high frequency power supply supplying a high frequency current to the holder.

5. The plasma processing apparatus according to claim 1, further comprising:
a coil fixed to the second member,
a high frequency current being supplied from the first high frequency power supply to the coil.

6. The plasma processing apparatus according to claim 1, wherein
a compression ratio of the conductive member is a compression ratio in a range in which cracks do not occur in the metal film.

7. The plasma processing apparatus according to claim 1, wherein
a compression ratio of the conductive member is determined by repeatedly compressing the conductive member while changing the compression ratio and by measuring an electrical resistance value of the conductive member each compression and release.

8. The plasma processing apparatus according to claim 1, wherein
a compression ratio of the conductive member is not less than 5% and not more than 25%.

9. The plasma processing apparatus according to claim 1, wherein
the resin material is elastic rubber.

10. The plasma processing apparatus according to claim 1, wherein
the resin material is fluororubber.

11. The plasma processing apparatus according to claim 1, wherein
the metal film includes at least one type of metal selected from the group consisting of nickel, chrome, titanium, tungsten, cobalt, gold, silver, copper, tin, and zinc.

12. The plasma processing apparatus according to claim 1, wherein
a film thickness of the metal film is not less than 200 nm.

13. The plasma processing apparatus according to claim 1, wherein
the plasma processing apparatus is a plasma etching apparatus.

14. A plasma processing method, comprising:
placing a work in a chamber including a first member and a second member, disposing a conductive member between the first member and the second member, and compressing the conductive member,
the conductive member including a metal film on a surface of a resin member,
the resin member being made of a resin material; and
generating plasma in the chamber by applying a high frequency current.

15. A conductive member conducting between parts of a plasma processing apparatus,
the parts being electrically isolated,
the conductive member comprising:
a rubber elastic base; and
a metal film plated on a surface of the rubber elastic base.

16. The conductive member according to claim 15, wherein
the conductive member is disposed in the plasma processing apparatus in a state of being compressed to cause a compression ratio to be in a range of 5 to 25%.

17. The conductive member according to claim 15, wherein
a film thickness of the metal film is 100 to 2000 nm.

18. The conductive member according to claim 17, wherein
the film thickness of the metal film is 100 to 1000 nm.

19. The conductive member according to claim 15, wherein
a material of the metal film is at least one type of metal selected from the group consisting of nickel, chrome, titanium, tungsten, cobalt, gold, silver, copper, tin, and zinc.

20. The conductive member according to claim 15, wherein
the metal film is a stacked film in which not less than two layers of metal layers made of mutually-different materials are stacked.
